(19) United States
(12) Patent Application Publication
(10) Pub. No.: US 2014/0177663 A1
(43) Pub. Date: Jun. 26, 2014

(54) Semiconductor Emitter and Method for Producing Useful Light from Laser Light

(71) Applicants: Klaus Finsterbusch, Berlin (DE); Ulrich Hartwig, Berlin (DE); Josef Kroell, Potsdam (DE); Nico Morgenbrod, Berlin (DE)

(72) Inventors: Klaus Finsterbusch, Berlin (DE); Ulrich Hartwig, Berlin (DE); Josef Kroell, Potsdam (DE); Nico Morgenbrod, Berlin (DE)

(21) Appl. No.: 14/234,905

(22) PCT Filed: Jun. 26, 2012
(86) PCT No.: PCT/EP2012/062325

§ 371 Date: Jan. 24, 2014

(30) Foreign Application Priority Data
Jul. 26, 2011 (DE) 102011079782.3

(51) Int. Cl. H01S 5/10

(52) U.S. Cl. CPC H01S 5/1017
USPC 372/45.01

(57) ABSTRACT

A semiconductor emitter (1; 12; 14; 18; 21; 23; 25; 27; 30; 32; 34), comprising an amplifier medium (2) and at least one waveguide (3, 4) arranged at the amplifier medium (2), wherein at least one light coupling-out region (10; 13; 15; 19; 20; 22; 24; 26a-e; 33; 35) is present at at least one waveguide (3), and at least one wavelength-converting phosphor (11; 28; 31r, 31g, 31b) is disposed downstream of at least one coupling-out region (10; 13; 15; 19, 20; 22; 24; 26a-e; 33; 35).

The invention relates to a semiconductor emitter comprising an amplifier medium introduced between an upper waveguide and a lower waveguide. The invention furthermore relates to a method for generating useful light from laser light. The invention can be used particularly advantageously for applications with a directional beam of rays, in particular for projectors and vehicle luminaires, in particular headlights.

Light sources having high light quality are required for many applications. These properties include firstly the spectrum, but also an emission characteristic and a luminance. Particularly in the case of video projection and wherever a directional beam of rays is required (e.g. in the case of an automobile headlight), light sources having a high luminance are typically required. High-pressure discharge lamps having a short arc are traditionally used for this purpose, which lamps convert electrical power into light on an extremely small volume (approximately one cubic millimeter). The use of light emitting diodes (LEDs) for this purpose, on account of their limited luminance, is practical only in some instances, e.g. in the case of pico-projectors in cellular phones or for a daytime running light in motor vehicles.

Recently, blue lasers in conjunction with downstream wavelength-converting dyes have also been used for this purpose (LARP, “Laser Activated Remote Phosphor”). For the LARP concept, the output beam of one or more semiconductor lasers is typically concentrated on a dye by means of mirrors and lenses and is at least partly wavelength-converted by said dye.

The object of the present invention is at least partly to overcome the disadvantages of the prior art and in particular to provide a semiconductor emitter which is particularly compact, inexpensive and safe to use.

This object is achieved in accordance with the features of the independent claims. Preferred embodiments can be gathered in particular from the dependent claims.

The object is achieved by means of a semiconductor emitter, comprising an amplifier medium and at least one waveguide arranged at the amplifier medium, wherein at least one light coupling-out region is present at at least one waveguide, and at least one wavelength-converting phosphor is disposed downstream of at least one coupling-out region.

Typically, an electromagnetic wave (“mode”) is generated by stimulated emission by means of the amplifier medium, said electromagnetic wave principally being situated in the amplifier medium or propagating there. In the case of a conventional semiconductor laser, said wave is usually coupled out by a partly transmissive (resonator) mirror directly from the amplifier medium in order to generate a laser beam. Whereas the laser beam in most semiconductor lasers is present as a narrowband and spatially and temporally coherent light beam, said beam in a superluminescence diode usually has a large line width, low temporal coherence, but high spatial coherence. The construction and manner of operation of semiconductor lasers (including superluminescence diodes) as such are well known and need not be explained further here.

The wave generated in the amplifier medium also penetrates with a relatively low, but non-negligible, intensity into the waveguide, the intensity decreasing with increasing distance from the amplifier medium. By virtue of the fact that at least one light coupling-out region for radiation, in particular light, is present in at least one waveguide, at least one light beam (also designated hereinafter as “useful light beam” for simplification) in addition to or instead of the laser beam usually coupled out by the partly transmissive mirror can be generated there. This useful light beam can, in particular, comprise incoherent light or consist incoherent light.

The power density of the useful light beam coupled out at a light coupling-out region is typically lower than the power density of the conventional laser beam, with the result that the useful light beam can also be radiated over short distances onto a (at least one) wavelength-converting phosphor without destroying the phosphor. Therefore, if at least one wavelength-converting phosphor is disposed downstream of at least one of the coupling-out regions, light having at least one wavelength that differs from the wavelength of the wave travelling in the amplifier medium can be generated directly at the semiconductor emitter or in relatively close proximity thereto. As a result, a particularly compact and robust wavelength-converting semiconductor emitter can be provided which can emit light having different wavelengths. In this regard, in particular it is possible to dispense with phosphor arranged remote from the semiconductor emitter (sometimes also called “remote phosphor”), and also with associated optical elements. This in turn makes possible a particularly inexpensive semiconductor+emitter that emits in a multicolored fashion (also achromatically). It is possible for no phosphor to be disposed downstream of at least one coupling-out region, with the result that in particular incoherent light having the original wavelength can be coupled out there.

A semiconductor emitter can be understood to mean, in particular, any semiconducting structure which generates electromagnetic radiation during its operation. The electromagnetic radiation can be light, in particular. The light can be visible light and/or non-visible light (e.g. infrared light or ultraviolet light). In this respect, the semiconductor emitter can in particular also be designated as a semiconductor light source.

The semiconductor emitter can be a semiconductor laser, in particular.

The semiconductor laser can comprise, in particular, a ridge laser (laser with ridge wave structure). In this case, the amplifier medium can be introduced in particular between an upper waveguide and a lower waveguide. The upper waveguide and the lower waveguide can be embodied in an integral fashion. The light coupling-out regions can be situated at the upper waveguide and/or at the lower waveguide.

However, the semiconductor emitter can e.g. also comprise a disk laser. In this type of laser, the wave oscillates at the edge of the disk laser (“edge mode”) in a circle. An optical feedback takes place as a result of a total internal reflection (TIR). An additional coating may be applied in the case of very small lasers if a required reflection angle cannot be attained. The wave or edge mode is spatially extensive in the case of the disk laser as well. Consequently, by means of a light coupling-out region present in the center of a disk of the disk laser, part of the edge mode can be coupled out and wavelength-converted. In other words, the at least one light coupling-out region can be situated in particular in a central region of a disk of the disk laser. Said at least one light coupling-out region can comprise in particular a plurality of light coupling-out regions in particular in a regular, in particular matrix-like, arrangement.

The semiconductor emitter can also comprise a laser diode, in particular a superluminescence diode.

The amplifier medium can be an amplifier layer, in particular. The amplifier medium can be integral or multipartite. A multipartite amplifier medium can also be regarded as a set of a plurality of amplifier media.

As already indicated above, the at least one useful light beam can be coupled out in addition to the customary laser beam.

Alternatively, (only) the at least one useful light beam may be coupled out instead of the laser light beam. Although in this semiconductor emitter laser light is still generated in the amplifier medium, it is no longer coupled out or used as such as a laser beam. Rather, only at least one useful light beam is generated. For this purpose, in particular, the feedback mirrors for the wave or mode present in the amplifier medium can be completely (100%) reflective. Such a semiconductor emitter is particularly energy-saving and can be designed in a targeted manner for light applications requiring multicolored (chromatic or achromatic) light. A further advantage is that the semiconductor emitter can be configured in such a way that no coherent radiation leaves the semiconductor emitter.

The at least one waveguide can be configured in particular in each case as at least one semiconductor layer (including a multilayer stack). Consequently, the at least one semiconductor layer can be at least partly light-transmissive. At least one waveguide can be configured as a p-doped semiconductor region. At least one other waveguide can be configured as an n-doped semiconductor region, or vice versa.

The at least one waveguide or semiconductor layer can be provided with at least one respective electrical connection, in particular with an external, in particular metallic, contact layer. At least one external contact layer can be embodied as a heat sink.

In one development, the semiconductor emitter comprises, at least at one waveguide, a plurality of light coupling-out regions arranged in a defined pattern. By way of example, the light coupling-out regions can be arranged in a row or in a matrix-like pattern.

In one configuration, the light coupling-out region is embodied as a cutout in the waveguide.

Through the cutout, a light coupling-out region is brought closer to the amplifier medium, as a result of which the useful light beam coupled out there can be intensified. By varying the form and/or the depth, it is possible to set the strength, e.g. a power density and/or an intensity, and/or a form of the useful light beam in a targeted manner.

In principle, the cutout can have any suitable form, e.g. a basic form that is rectangular in cross section, or a box form.

In another configuration, the cutout has a form that tapers in the direction of the amplifier medium, in particular a basic form that is V-shaped in cross section.

This basic form facilitates production of the cutout by conventional etching processes. Moreover, it thus becomes possible for a useful light beam generated at the cutout to be directed, in particular concentrated, to a greater extent. In particular, a beam width of the useful light beam can thus be limited.

The vertex of the “V” can be pointed or flattened.

In one development, at least one cutout has a cone-like or truncated-cone-like basic form. The latter is particularly suitable for use with a disk laser, but is not restricted thereto. This development makes it possible to generate a greatly concentrated, in particular rotationally symmetrical light beam.

In one development, furthermore, at least one cutout has a pyramid-like or truncated-pyramid-like basic form. This development makes it possible to generate a greatly concentrated light beam, wherein the cutout can be produced in a simple manner using semiconductor processing methods.

In another development, at least one cutout has a trench-like basic form having a long extent in one direction. The trench may be, in particular, a trench having a V-shaped cross section. The trench-like basic form makes possible a high luminous flux and can be produced in a simple manner using semiconductor processing methods.

Cutouts having different basic forms can be used.

At least one cutout, in particular a trench, can extend over an entire width of a waveguide. However, it may be advantageous for the cutouts to be surrounded circumferentially by a waveguide, which makes it easier to make electrical contact with said waveguide (without electrical bridges, etc.).

In yet another configuration, the semiconductor emitter has a plurality of light coupling-out regions having different depths.

In particular an improved adjustability of an intensity distribution of a resulting overall useful light beam can thus be achieved.

In one development, at least one cutout is arranged or formed at a distance from the amplifier medium. In other words, said at least one cutout does not extend as far as the amplifier medium. An intensity or power density of a light beam coupled out at the cutout can thus be kept low, which fosters inter alia a longevity of the at least one assigned phosphor. Moreover, light generation in the amplifier medium is thus not, or only insignificantly, disturbed.

In another configuration, at least one cutout extends at least as far as into the amplifier medium. An intensity or power density of a light beam coupled out at the cutout can be greatly increased as a result.

In one development; at least one cutout extends through at least one amplifier medium.

This makes possible a particularly high strength, e.g. intensity and/or power density, of the useful light beam assigned to said light coupling-out region.

In one configuration, furthermore, the cutout is at least partly filled with the at least one phosphor.

A particularly compact and inexpensive semiconductor emitter can be provided as a result. A cutout can be completely filled with phosphor, thus resulting in a particularly high degree of conversion. Alternatively, e.g. only the surface of the cutout may be coated with phosphor, which enables a useful luminous flux emitted from the cutout to be directed and/or shaped more simply. Particularly in interaction with a tapering cutout, a beam width of the useful luminous flux can thus be or remain limited.

In one configuration, moreover, the light coupling-out region has a scattering structure at a free surface of the waveguide.

Said scattering structure can be present at a surface of a cutout or at a cutout-free region of at least one waveguide. By means of the scattering structure, in particular, a total reflection at the surface region equipped with the scattering structure can be disturbed and light can thus be coupled out. It is thus possible to bring about or amplify a coupling-out of light using simple means.

The scattering structure can be, for example, a roughened region or a roughening. Alternatively or additionally, the scattering structure can be, for example, a body which makes contact with the waveguide and the refractive index of which differs significantly from the refractive index of the waveguide with which contact is made, and thus brings about the useful light beam.

In one configuration, moreover, a light guiding structure is disposed downstream of the light coupling-out region and is designed to guide a light beam emerging from the light coupling-out region to at least one phosphor.

A particularly diversely configured phosphor region can thus be produced. Moreover, the light emerging from the light coupling-out region can thus be shaped particularly diversely and precisely. The light guiding structure may be, for example, an optical waveguide equipped with phosphor as filler. The light guiding structure may also comprise a hollow waveguide, in the hollow interior of which the light is guided and on the inner side of which the phosphor is present. The light guiding structure may be placed for example perpendicularly onto a light coupling-out region.

In another configuration, a wavelength-selective filter is disposed downstream of the at least one phosphor of at least one of the coupling-out regions and it transmits wavelength-converted light and blocks non-wavelength-converted light.

The wavelength-selective filter may be, in particular, a wavelength-selective reflector which transmits wavelength-converted light and reflects non-wavelength-converted light back into the semiconductor emitter. This enables a wavelength-converted useful light beam having color purity to be coupled out since non-wavelength-converted color components are suppressed. Moreover, light loss of the non-wavelength-converted light and thus a power loss of the laser beam can thus be reduced if the latter is used. By contrast, an extent to which the wavelength-converted light is coupled out is not, or not significantly, impaired.

The at least one wavelength-selective reflector can comprise or be, for example, a dichroic mirror. Another possibility consists in a coating with a thin gold layer, which is e.g. transparent to blue light and reflective to red light.

The object is also achieved by means of a method for generating, in particular non-coherent, useful light from laser light, wherein the useful light is coupled out from at least one waveguide arranged at an amplifier medium for generating the laser light. This method makes possible the same advantages as the semiconductor emitter and can be configured analogously.

The above-described properties, features and advantages of this invention and also the way in which they are achieved will become clearer and more clearly understood in connection with the following schematic description of exemplary embodiments which are explained in greater detail in association with the drawings. In this case, identical or identically acting elements may be provided with identical reference signs for the sake of clarity.

FIG. 1 shows, as a sectional illustration in side view, a conventional semiconductor laser in comparison with an inventive semiconductor emitter;

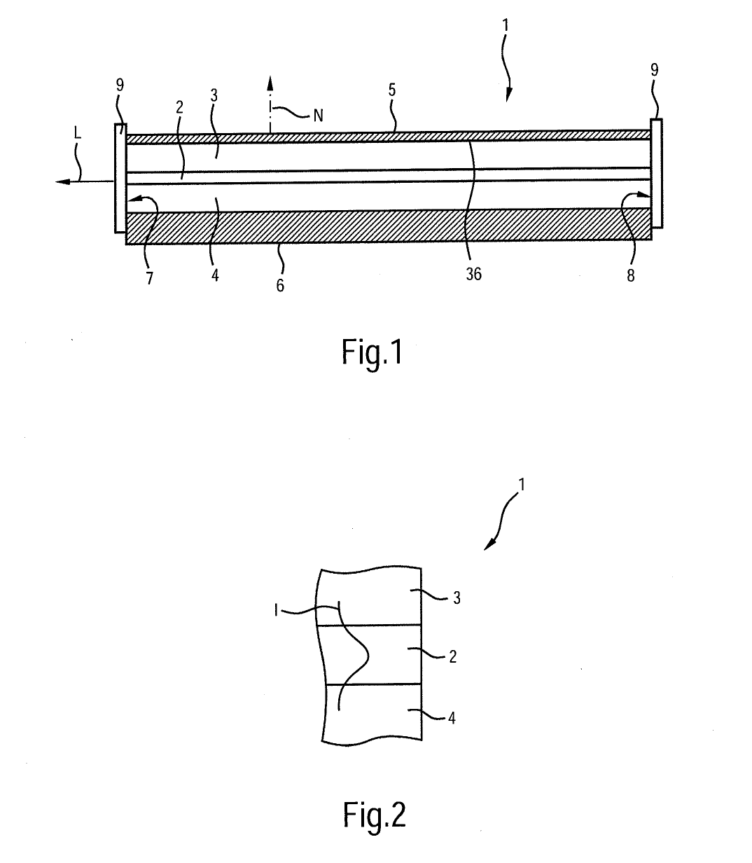

FIG. 2 shows, as a sectional illustration in side view, a typical intensity profile of a standing wave in the semiconductor laser and the semiconductor emitter;

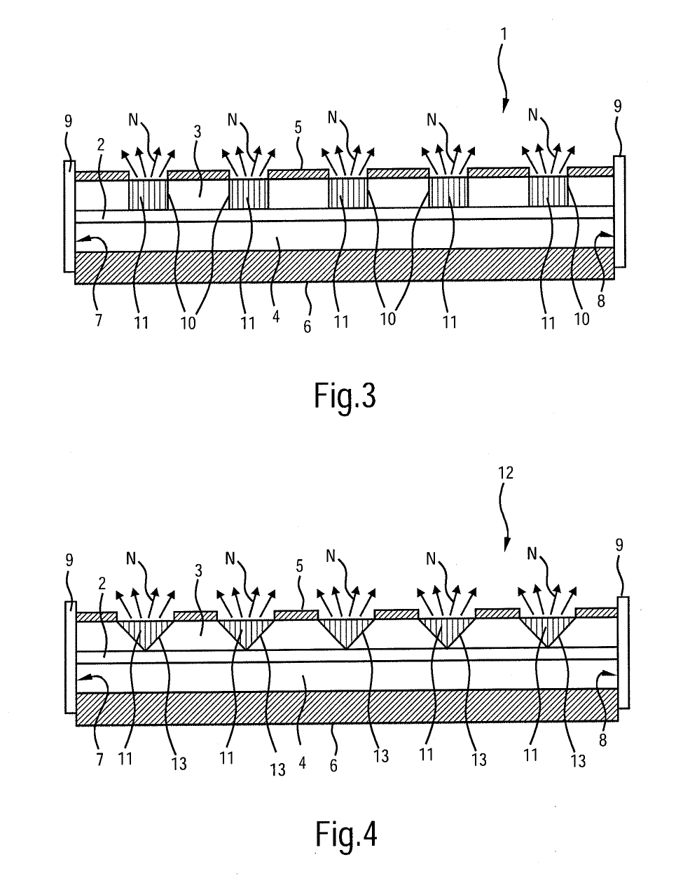

FIG. 3 shows, as a sectional illustration in side view, a semiconductor emitter in accordance with a first embodiment;

FIG. 4 shows, as a sectional illustration in side view, a semiconductor emitter in accordance with a second embodiment;

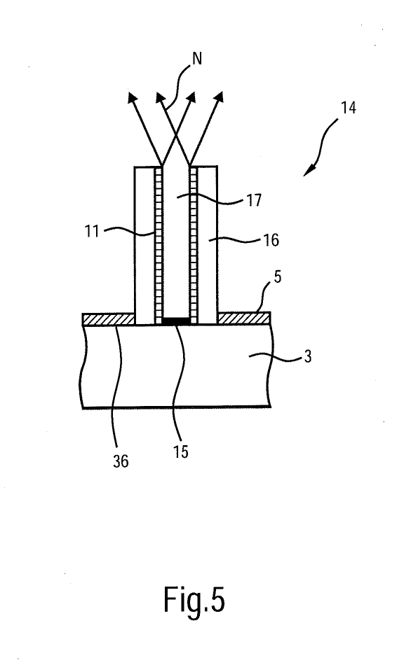

FIG. 5 shows, as a sectional illustration in side view, an excerpt from a semiconductor emitter in accordance with a third embodiment;

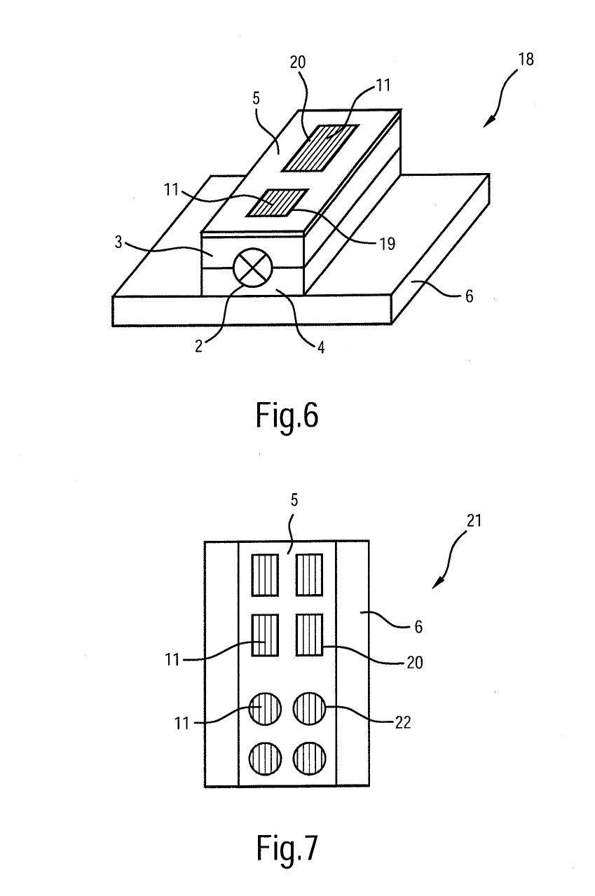

FIG. 6 shows, in a view obliquely from above, a semiconductor emitter in accordance with a fourth embodiment;

FIG. 7 shows, in a view from above, a semiconductor emitter in accordance with a fifth embodiment;

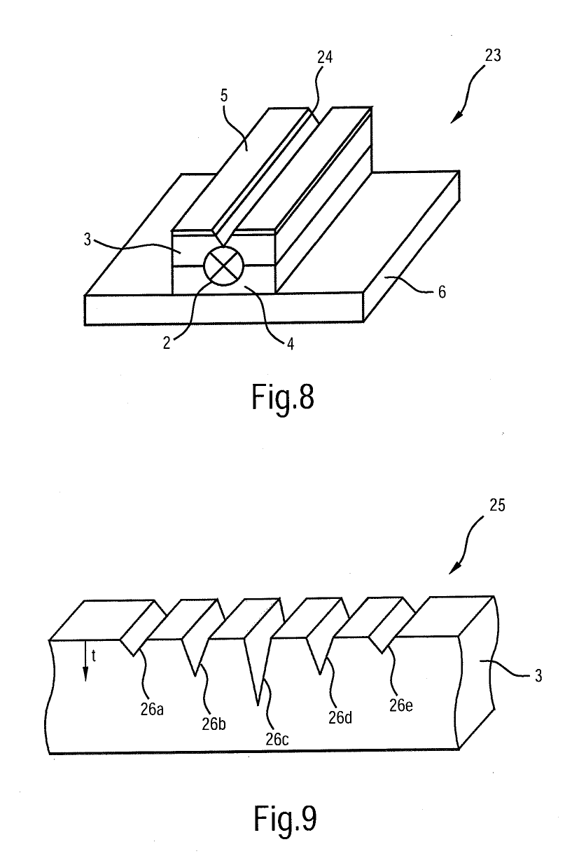

FIG. 8 shows, in a view obliquely from above, a semiconductor emitter in accordance with a sixth embodiment;

FIG. 9 shows, in a view obliquely from above, a semiconductor emitter in accordance with a seventh embodiment;

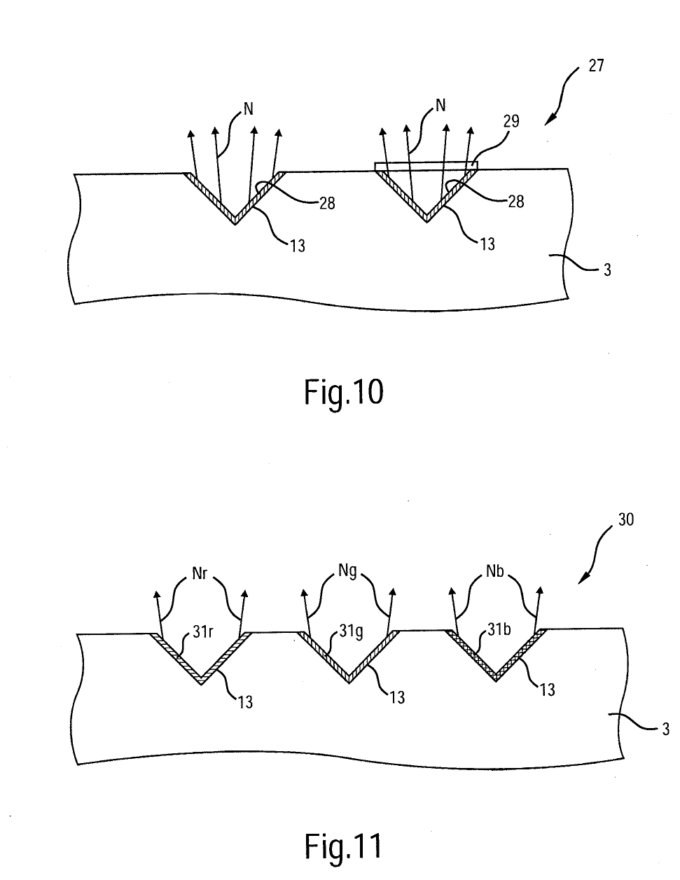

FIG. 10 shows, as a sectional illustration in side view, an excerpt from a semiconductor emitter in accordance with a eighth embodiment;

FIG. 11 shows, as a sectional illustration in side view, an excerpt from a semiconductor emitter in accordance with a ninth embodiment;

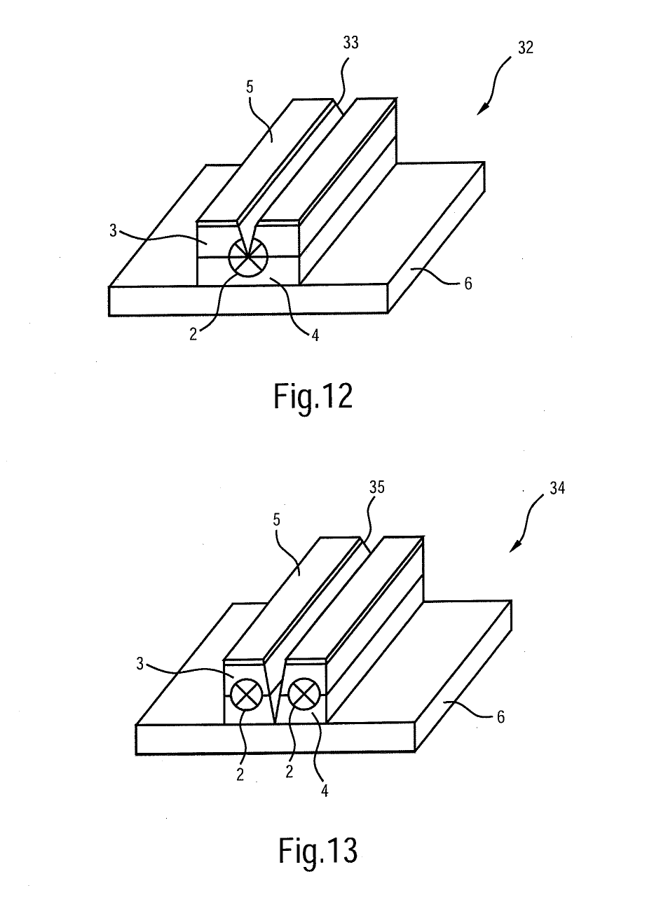

FIG. 12 shows, in a view obliquely from above, an excerpt from a semiconductor emitter in accordance with a tenth embodiment; and

FIG. 13 shows, in a view obliquely from above, an excerpt from a semiconductor emitter in accordance with an eleventh embodiment.

FIG. 1 shows, as a sectional illustration in side view, a conventional semiconductor laser in comparison with a semiconductor emitter 1 in accordance with a first embodiment. Both the conventional semiconductor laser and the semiconductor emitter 1 comprise an amplifier medium 2 serving as an “active zone” for generating laser light by stimulated emission in a manner that is known in principle.

An upper waveguide 3 is arranged at the top side of the amplifier medium 2. The upper waveguide 3 simultaneously constitutes a p-doped semiconductor region and can for example consist of a plurality of layers or constitute a layer stack. Analogously, a lower waveguide 4 is arranged at the underside of the amplifier medium 2, which lower waveguide constitutes an n-doped semiconductor region and can consist of a plurality of layers. On the outer side, the upper waveguide 3 and the lower waveguide 4 are covered with an upper contact layer 5 and a lower contact layer 6, respectively, for making electrical contact. By way of example, the lower contact layer 6 can also be configured as a heat sink. At a front side 7 and a rear side 8 adjoining opposite narrow sides of the amplifier medium 2, there are situated two mirrors 9 for establishing the standing wave in the amplifier medium 2.

During operation, laser light is generated in the amplifier medium 2 in a known manner. As shown in FIG. 2 on the basis of an intensity profile I, the laser light or the corresponding wave or mode is concentrated in the amplifier medium 2. However, the laser light also penetrates into the upper waveguide 3 and the lower waveguide 4, the intensity I decreasing there with increasing distance from the amplifier medium 2. At an outer surface 36 (adjoining the contact layers 5 and 6, respectively) of the waveguides 3, 4, the intensity I is practically negligibly low.

In a conventional semiconductor laser, one of the (resonator) mirrors 9, e.g. the front-side mirror, is partly transmissive, such that once a laser threshold has been reached, laser light L can emerge through this semitransmissive mirror 9 and can be used as useful light.

In the semiconductor emitter 1, alternatively or additionally light (“useful light” N, indicated here in a dash-dotted manner) is coupled out via at least one of the waveguides 3, 4. This useful light N may be, in particular, non-coherent. If this light is emitted as an alternative to the laser light L, in particular both mirrors 9 can be non-transmissive mirrors (having a reflectance of 100%) and no laser light L is coupled out, but rather is only generated internally.

FIG. 3 shows, as a sectional illustration in side view, the semiconductor emitter 1 in accordance with a first embodiment. For coupling out the light via the here upper waveguide 3, coupling-out regions in the form of a plurality of rectangular or box-shaped cutouts 10 are present there. Said cutouts 10 have a depth such that they extend as far as the amplifier medium 2 or are led close to the amplifier medium 2. Consequently, the cutouts 10 extend as far as into a region of the upper waveguide 3 in which the intensity I of the (internal) laser light is non-negligible or is comparatively high. The laser light is coupled out at the cutouts 10, and loses its coherence in the process. This coupled-out light is also designated hereinafter as “primary light”.

The cutouts 10 are completely filled with phosphor 11. The phosphor 11 (which is therefore disposed optically downstream of an associated cutout 10), converts the primary light coupled out there at least partly into light having a different wavelength and generates a light beam (also called “useful light beam N” hereinafter) which, depending on the degree of conversion, comprises only wavelength-converted light or mixed light containing partly wavelength-converted light and partly primary light. The phosphor can be a single phosphor or contain a plurality of phosphors which generate e.g. wavelength-converted light having different peak wavelengths.

The semiconductor emitter 1 can therefore generate wavelength-converted light in a particularly compact and robust manner. There is no longer a need for a downstream optical unit for guiding to a remotely arranged phosphor. In contrast for example to an arrangement in the laser beam L, the phosphor 11 is generally not destroyed owing to the lower power density. Moreover, processing of the upper waveguide 3 and application of the phosphor 11 can be achieved without losses of service life. By contrast, application on a front side 7 (or front-side facet) would result in the following problems: the power densities there are very high and would destroy the phosphor. Specifically in the case of a blue GaN laser, the front side 7 could be damaged very easily. In this regard, e.g. contact with air humidity or oxygen leads to failure within a few hours. Moreover, the optical feedback is impaired.

For coupling out laser light more effectively, the cutouts 10 can have a scattering structure, e.g. can be at least partly roughened.

FIG. 4 shows, as a sectional illustration in side view, a semiconductor emitter 12 in accordance with a second embodiment. The semiconductor emitter 12 is constructed similarly to the semiconductor emitter 1 of the first embodiment and differs therefrom in the form of the cutouts 13. The cutouts 13 have a V-shape in cross section. The cutouts 13 can be present e.g. as elongate trenches, pyramidal or conical depressions. The V-shape makes possible a useful light beam N having a smaller aperture angle.

FIG. 5 shows, as a sectional illustration in side view, an excerpt from a semiconductor emitter 14 in accordance with a third embodiment. Here at least one light coupling-out region in the form of a scattering structure 15 is formed on a free surface 36 of the upper waveguide 3. The scattering structure 15 can be present e.g. in the form of a local roughening. Light can be coupled out from the upper waveguide 3 at the scattering structure 15.

A light guiding structure in the form of a perpendicular tube 16 is disposed downstream of the scattering structure 15. One opening of the tube 16 is covered by the scattering structure 15, while the other opening is light-transmissive. An inner side of the tube 16 is covered with phosphor 11. Light coupled out at the scattering structure 15 is thus guided through the inner cavity 17 of the tube 16, wherein the light at least for the most part impinges on the inner wall and thus on the phosphor 11 and is wavelength-converted. This arrangement makes possible a particularly targeted and substantial shaping and orientation of a useful light beam N emerging from the tube 16.

This arrangement can also be combined with a cutout, e.g. the cutout 10, wherein the scattering structure 15 is present for example at a base of the cutout and the tube 16 is also mounted there. An intensity or a luminous flux of the useful light beam N can thus be set, in particular amplified, in a targeted manner.

FIG. 6 shows, in a view obliquely from above, a semiconductor emitter 18 in accordance with a fourth embodiment. This semiconductor emitter 18 comprises an elongated amplifier medium 2, which is surrounded circumferentially by the upper waveguide 3 and the lower waveguide 4.

The cutouts 19 and 20 do not extend over the entire width b of the upper waveguide and therefore also do not extend over the width b of the upper contact layer 5, which makes possible a continuous upper contact layer 5 and facilitates electrical contact-making.

FIG. 7 shows, in a view from above, a semiconductor emitter in accordance with a fifth embodiment, which can be constructed e.g. similarly to the semiconductor emitter 18. The semiconductor emitter 21 shows the possibility of simultaneously using cutouts 20, 22 of different forms. Both types of cutouts 20, 22 here have a V-shaped cross section, wherein the cutouts 20 can have e.g. a pyramidal form and the cutouts 22 can have e.g. a conical form. This enables particularly diverse useful light beams to be generated. The figure also shows that the cutouts 20, 22 can be arranged for example in a matrix-like pattern (here in each case in a 2×2 pattern), in order to increase a luminous flux easily in a scalable manner.

FIG. 8 shows, in a view obliquely from above, a semiconductor emitter 23 in accordance with a sixth embodiment having a construction similar to the semiconductor emitter 18. Here the V-shaped cutout 24 now extends along the amplifier medium 2, which makes possible particularly simple production and a high luminous flux. The phosphor is not depicted, merely for the sake of simplified illustration.

FIG. 9 shows, in a view obliquely from above, an upper waveguide 3 of a semiconductor emitter 25 in accordance with a seventh embodiment having a plurality—here for example five—of cutouts 26a-e. A depth t of the cutouts 26a-e differs in some instances, and therefore so does a power density or a luminous flux of the useful light beams which can be emitted by the cutouts 26a-e. A luminous flux emitted by the semiconductor emitter 25 can thus be set particularly diversely.

FIG. 10 shows, as a sectional illustration in a side view, an excerpt from an upper waveguide 3 of a semiconductor emitter 27 in accordance with an eighth embodiment. Unlike in the case of the semiconductor emitter 12, the cutouts 13 are now no longer completely filled with phosphor, but rather are only coated with a phosphor layer 28. As a result, an aperture angle of the useful light beam N can be decreased further.

Moreover, a proportion of a non-wavelength-converted light can be set in a targeted manner, e.g. in order to generate a useful light beam N of mixed light having a defined cumulative color locus. By way of example, the primary light may be blue light and the dye may convert blue light into yellow light. The useful light beam N can then consist, in particular, of white mixed light generated by a blue-yellow light mixture.

In order, if appropriate, to eliminate a proportion of a non-wavelength-converted light from the useful light beam N, e.g. a filter 29, indicated at the right-hand cutout 13, can be disposed downstream of the phosphor 11, said filter transmitting only wavelength-converted light. Non-wavelength-converted light may be reflected in particular back into the upper waveguide 3 by means of a filter 29.

FIG. 11 shows, as a sectional illustration in side view, an excerpt from an upper waveguide 3 of a semiconductor emitter 30 in accordance with a tenth embodiment. The semiconductor emitter 30 is constructed similarly to the semiconductor emitter 27, except that now different phosphors 31r, 31g and 31b are present in the cutouts 13. Useful light beams Nr, Ng and Nb, respectively, of different colors or spectral compositions can thus be generated.

By way of example, the laser light generated in the amplifier medium 2 and thus the primary light may be ultraviolet light, which is converted by the phosphors 31r, 31g and 31b as completely as possible into red, green and blue light or into red, green and blue useful light beams Nr, Ng and Nb, respectively. A respective UV filter (not illustrated) can ensure that the semiconductor emitter 30 emits no ultraviolet radiation.

Alternatively or additionally, there may also be no phosphor disposed downstream of at least one cutout 13, in order to be able to couple out useful light having the wavelength of the primary light, e.g. as a color component of a mixed light.

FIG. 12 shows a semiconductor emitter 32 similar to the semiconductor laser 23, the trench-like cutout 33 now extending as far as into the amplifier medium 2. A useful light beam having a particularly high luminous flux is thus generated. For only slight attenuation of the laser light generated in the amplifier medium 2, the cutout 33 extends parallel to a longitudinal extent of the amplifier medium 2. Here, too, purely for clarity of illustration, no phosphor (filled in or present as a layer) is depicted, but it is present.

In an alternative configuration, at least one cutout can also project through the amplifier medium 2.

FIG. 13 shows a semiconductor emitter 34 similar to the semiconductor laser 23, a trench-like cutout 35 that is V-shaped in cross section extending through between two separate amplifier media 2. This makes possible a high luminous flux of the associated useful light beam without generation of laser light being impaired. Here, too, purely for clarity of illustration, no phosphor (filled in or present as a layer) is depicted, but it is present.

Although the invention has been more specifically illustrated and described in detail by means of the exemplary embodiments shown, the invention is nevertheless not restricted thereto, and other variations can be derived therefrom by the person skilled in the art, without departing from the scope of protection of the invention.

In this regard, in all the exemplary embodiments, light coupling-out regions can interact with different phosphors. Moreover, filters can be used in all the exemplary embodiments.

In addition, types of semiconductor laser forming a basis for a semiconductor emitter which differ from those shown can also be used, e.g. a disk laser.

Moreover, there may be no phosphor disposed downstream of at least one cutout or a region of a cutout.

Generally, different, in particular differently colored, useful light beams can be led out separately from a semiconductor emitter or be led out as mixed light.

1. A semiconductor emitter, comprising an amplifier medium and at least one waveguide arranged at the amplifier medium, wherein
at least one light coupling-out region is present at at least one waveguide, and
at least one wavelength-converting phosphor is disposed downstream of at least one coupling-out region.

2. The semiconductor emitter, as claimed in claim 1, wherein the light coupling-out region is embodied as a cutout in the waveguide.

3. The semiconductor emitter as claimed in claim 2, wherein the cutout has a form that tapers in the direction of the amplifier medium.

4. The semiconductor emitter as claimed in claim 2, wherein the semiconductor emitter has a plurality of cutouts having a different depth.

5. The semiconductor emitter as claimed in claim 2, wherein at least one cutout extends at least as far as into the amplifier medium.

6. The semiconductor emitter as claimed in claim 2, wherein the cutout is at least partly filled with the at least one phosphor.

7. The semiconductor emitter as claimed in claim 1, wherein the light coupling-out region has a scattering structure at a free surface of the waveguide.

8. The semiconductor emitter as claimed in claim 1, wherein a light guiding structure is disposed downstream of the light coupling-out region and is designed to guide a light beam emerging from the light coupling-out region to at least one phosphor.

9. The semiconductor emitter as claimed in claim 1, wherein a wavelength-selective filter, is disposed downstream of the at least one phosphor of at least one of the coupling-out regions and it transmits light wavelength-converted by the phosphor and blocks non-wavelength-converted light.

10. A method for generating useful light from laser light, wherein the useful light is coupled out from at least one waveguide arranged at an amplifier medium for generating the laser light.

11. The semiconductor emitter as claimed in claim 2, wherein the cutout has a basic form that is V-shaped in cross section and tapers in the direction of the amplifier medium.

12. The semiconductor emitter as claimed in claim 1, wherein a wavelength-selective filter, in the form of a reflector, is disposed downstream of the at least one phosphor of at least one of the coupling-out regions and said filter transmits light wavelength-converted by the phosphor and blocks non-wavelength-converted light by reflecting the light back into the semiconductor emitter.
